(19) United States
(12) Patent Application Publication
(10) Pub. No.: US 2023/0135542 A1
(43) Pub. Date: May 4, 2023

(54) CONSTANT VOLTAGE GENERATION CIRCUIT

(71) Applicant: Rohm Co., Ltd., Kyoto (JP)

(72) Inventor: Makoto Yasusaka, Kyoto (JP)

(21) Appl. No.: 17/798,619

(22) PCT Filed: Feb. 9, 2021
(86) PCT No.: PCT/JP2021/004749

§ 371 Date: Aug. 10, 2022

(30) Foreign Application Priority Data
Feb. 25, 2020 (JP) 2020029233
Feb. 25, 2020 (JP) 2020029235

(51) Int. Cl. G11C 5/14; G05F 1/56

(52) U.S. Cl. CPC G11C 5/147; G05F 1/56

(57) ABSTRACT

A constant voltage generation circuit includes a depression type first transistor and an enhancement type second transistor that constitute an ED type reference voltage source, and a resistor connected between gate and source of the first transistor. For instance, the first transistor and the second transistor are NMOSFETs. In addition, for example, the first transistor has a drain connected to an application terminal of an input voltage, and the second transistor has a source connected to a reference potential terminal. Further, gates of the first transistor and the second transistor and a drain of the second transistor are connected to an output terminal of a constant voltage.

### TECHNICAL FIELD

The invention disclosed in this specification relates to a constant voltage generation circuit.

### BACKGROUND ART

Conventionally, as one type of a constant voltage generation circuit, an ED type constant voltage source is widely known, in which a depression type metal oxide semiconductor field effect transistor (NMOSFET) and an enhancement type NMOSFET are combined (see, for example, Patent Citation 1).

### LIST OF CITATIONS

### Patent Literature

Patent Citation 1: JP-A-2011-029912

### SUMMARY OF THE INVENTION

### Technical Problem

However, the conventional constant voltage generation circuit described above has room for improvement in output accuracy.

In view of the task described above found by the inventor of this application, it is an object of the invention disclosed in this specification to provide a constant voltage generation circuit that has high output accuracy.

### Means for Solving the Problem

For instance, a constant voltage generation circuit disclosed in this specification includes a depression type first transistor and an enhancement type second transistor that constitute an ED type reference voltage source, and a resistor connected between gate and source of the first transistor.

Further for example, a constant voltage generation circuit disclosed in this specification includes a depression type first transistor and an enhancement type second transistor that constitute an ED type reference voltage source, and a depression type third transistor that is connected to a drain of the first transistor and has a larger W/L than the first transistor.

Note that other features, elements, steps, advantages, and characteristics of the present invention will become more apparent from the description of the embodiments given below and the related attached drawings.

### Advantageous Effects of the Invention

According to the invention disclosed in this specification, a constant voltage generation circuit that has high output accuracy can be provided.

### BRIEF DESCRIPTION OF DRAWINGS

FIG. 1 is a diagram illustrating a comparative example of a constant voltage generation circuit.

FIG. 2 is a diagram illustrating a first embodiment of the constant voltage generation circuit.

FIG. 3 is a diagram illustrating a drain current variation suppression effect by adding a resistor.

FIG. 4 is a diagram illustrating a second embodiment of the constant voltage generation circuit.

FIG. 5 is a diagram illustrating a third embodiment of the constant voltage generation circuit.

FIG. 6 is a diagram illustrating a fourth embodiment of the constant voltage generation circuit.

FIG. 7 is a diagram illustrating a fifth embodiment of the constant voltage generation circuit.

FIG. 8 is a diagram illustrating a sixth embodiment of the constant voltage generation circuit.

FIG. 9 is a diagram illustrating Vds(M1)-Id characteristic and VIN-VREF characteristic.

FIG. 10 is a diagram illustrating a seventh embodiment of the constant voltage generation circuit.

FIG. 11 is a diagram illustrating drain current variation suppression effect by adding a transistor.

FIG. 12 is a diagram illustrating VIN-Vds(M1) characteristic.

FIG. 13 is a diagram illustrating an eighth embodiment of the constant voltage generation circuit.

FIG. 14 is a diagram illustrating a ninth embodiment of the constant voltage generation circuit.

FIG. 15 is a diagram illustrating a tenth embodiment of the constant voltage generation circuit.

FIG. 16 is a diagram illustrating an eleventh embodiment of the constant voltage generation circuit.

FIG. 17 is a diagram illustrating a twelfth embodiment of the constant voltage generation circuit.

FIG. 18 is a diagram illustrating a thirteenth embodiment of the constant voltage generation circuit.

### DESCRIPTION OF EMBODIMENTS

### Comparative Example

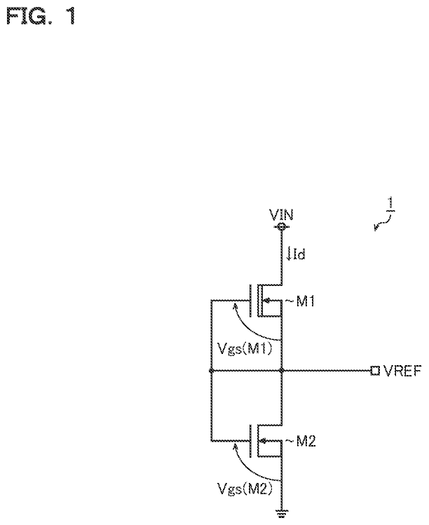

FIG. 1 is a diagram illustrating a comparative example (an example of a basic structure to be compared with embodiments described later) of a constant voltage generation circuit. A constant voltage generation circuit 1 of this comparative example is a so-called ED type reference voltage source, which includes a depression type N-channel MOS field effect transistor M1 and an enhancement type N-channel MOS field effect transistor M2.

Note that the depression type means one in which drain current flows even at a gate-source voltage of 0 V. In contrast, the enhancement type means one in which drain current does not flow at a gate-source voltage of 0 V.

The transistor M1 has a drain connected to an application terminal of an input voltage VIN (e.g. 5 V). The transistor M2 has a source and a backgate that are connected to a ground terminal (i.e. a reference potential terminal). The gate, source, and backgate of the transistor M1, and the gate and drain of the transistor M2 are all connected to an output terminal of a constant voltage VREF.

In the constant voltage generation circuit 1 of this comparative example, the gate and source of the transistor M1 are short-circuited to each other, and hence the transistor M1 has a gate-source voltage Vgs(M1) of 0 V. Therefore, the transistor M1 functions as a constant current source that generate constant drain current Id, and constant bias current (i.e. the drain current Id of the transistor M1) flows in the transistor M2. As a result, the constant voltage VREF corresponding to gate-source voltage Vgs(M2) of the transistor M2 is generated.

<Consideration about Process Variation>

It is known that ON threshold value voltage Vth(M1) of the transistor M1 is easily affected by process variation. For instance, if the ON threshold value voltage Vth(M1) shifts to the negative side, the drain current Id becomes larger than standard value Id0, and hence the constant voltage VREF is deviated from a desired value.

In this way, a main factor of output variation in the constant voltage generation circuit 1 is a large shift of the drain current Id due to the process variation of the ON threshold value voltage Vth(M1).

In the following description, in view of the above consideration, novel embodiments are proposed that can suppress variation of the drain current Id due to the process variation so that output accuracy of the constant voltage VREF can be improved.

### First Embodiment

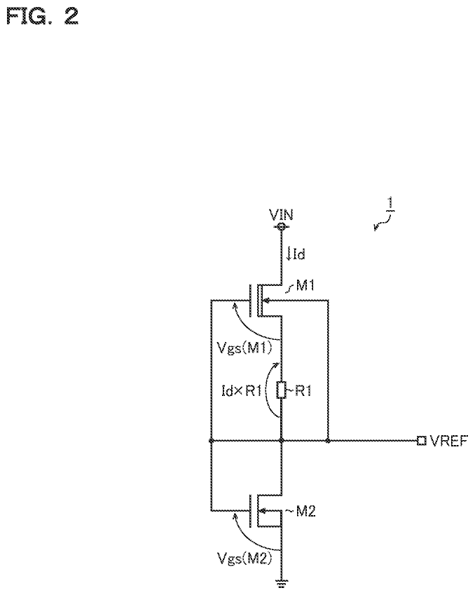

FIG. 2 is a diagram illustrating a first embodiment of the constant voltage generation circuit. The constant voltage generation circuit 1 of this embodiment is based on the comparative example (FIG. 1) described above and further includes a resistor R1.

A first terminal of the resistor R1 is connected to the source of the transistor M1. A second terminal of the resistor R1 is connected to the gate and backgate of the transistor M1 and the output terminal of the constant voltage VREF. In this way, the resistor R1 is connected between the gate and source of the transistor M1 and between the backgate and source of the transistor M1.

Note that it is preferred to use a base resistor having a positive temperature characteristic as the resistor R1, for example. However, the type of the resistor R1 is not limited to this, but it may be possible to use a poly resistor having a negative temperature characteristic as the resistor R1, for example.

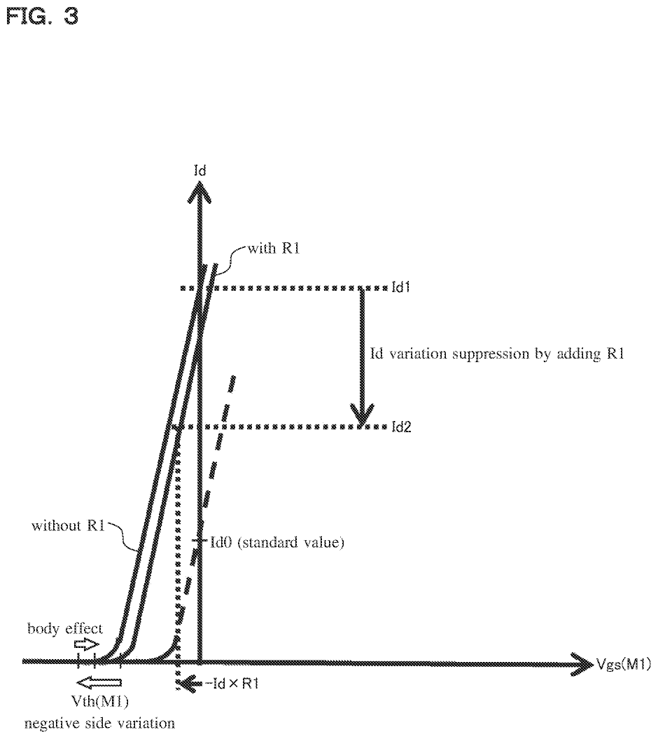

FIG. 3 is a diagram illustrating variation suppression effect of the drain current Id by adding the resistor R1. Note that the horizontal axis represents the gate-source voltage Vgs(M1) of the transistor M1, while the vertical axis represents the drain current Id flowing in the transistor M1.

If the resistor R1 is not disposed (corresponding to the comparative example described above), the gate-source voltage Vgs(M1) of the transistor M1 is 0 V. Therefore, if the ON threshold value voltage Vth(M1) of the transistor M1 shifts to the negative side, the drain current Id flowing in the transistor M1 becomes larger than the standard value Id0 (Id shifts from Id0 to Id1).

In contrast, if the resistor R1 is connected to the source of the transistor M1 (corresponding to the first embodiment), a potential difference (=Id×R1) corresponding to the drain current Id is generated between both terminals of the resistor R1.

Therefore, the gate-source voltage Vgs(M1) of the transistor M1 is shifted to the negative side (Vgs(M1)=−Id×R1).

In other words, when the ON threshold value voltage Vth(M1) of the transistor M1 shifts to the negative side, as the drain current Id increases more, the source potential of the transistor M1 is raised more. Consequently, the gate-source voltage Vgs(M1) of the transistor M1 is shifted to the negative side more. As a result, ON resistance of the transistor M1 is increased, and hence the increase of the drain current Id can be suppressed.

Note that if the drain current Id flowing in the transistor M1 is 100 nA or more and less than 1 μA (e.g. 100 nA), the resistance of the resistor R1 should be 100 ka or more and less than 1 MΩ (e.g. 100 kΩ), for example. With this element design, the shift amount of the gate-source voltage Vgs(M1) can be set to approximately −100 mV (variation corresponding to the drain current Id).

In addition, it can be said that the resistor R1 is connected between the source and the backgate of the transistor Mt. Therefore, corresponding to the drain current Id, a difference between the source potential and the backgate potential of the transistor M1 is also generated, and hence a so-called body effect occurs.

Note that the above-mentioned body effect is one of device characteristics of a MOSFET, and means a phenomenon in which a voltage applied between source and backgate causes an increase of a depletion layer region of the MOSFET, so that the ON threshold value voltage varies.

For instance, when the ON threshold value voltage Vth(M1) of the transistor M1 shifts to the negative side, as the drain current Id increases more, the source potential of the transistor M1 is raised more. Consequently, the above-mentioned body effect works so that the ON threshold value voltage Vth(M1) of the transistor M1 is shifted to the positive side, i.e., that the shift of the ON threshold value voltage Vth(M1) to the negative side is suppressed. As a result, the ON resistance of the transistor M1 is increased, and hence the increase of the drain current Id can be suppressed.

In this way, in the constant voltage generation circuit 1 of this embodiment, when the drain current Id increases, both the negative side shift effect of the gate-source voltage Vgs(M1) and the positive side shift effect (i.e. the body effect) of the ON threshold value voltage Vth(M1) work due to the insertion of the resistor R1. Therefore, an increase of the drain current Id can be suppressed (Id shifts from Id1 to Id2), output accuracy of the constant voltage VREF can be improved, and further temperature characteristics can be improved.

For instance, if the resistor R1 is not disposed, the output accuracy of the constant voltage VREF is ±4% to 6%. In contrast, if the resistor R1 is disposed, the output accuracy of the constant voltage VREF is improved to be approximately ±1%.

In contrast, if the drain current Id shifts to be smaller than the standard value Id0, a voltage is hardly generated between both terminals of the resistor R1. Therefore, each of the negative side shift effect of the gate-source voltage Vgs(M1) and the positive side shift effect (i.e. body effect) of the ON threshold value voltage Vth(M1) does not work, and hence the effect of adding the resistor R1 substantially vanishes.

### Second Embodiment

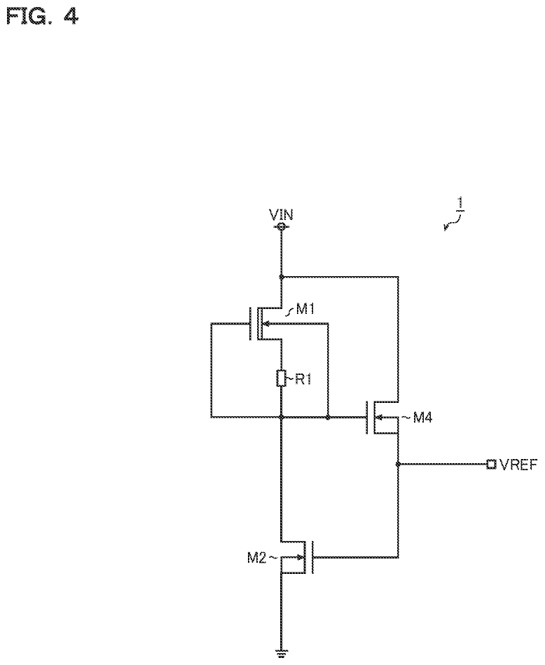

FIG. 4 is a diagram illustrating a second embodiment of the constant voltage generation circuit. The constant voltage generation circuit 1 of this embodiment is based on the first embodiment (FIG. 2) described above and further includes an enhancement type N-channel MOS field effect transistor M4.

The transistor M4 has a drain connected to the application terminal of the input voltage VIN. The transistor M4 has agate connected to the gate and backgate of the transistor M1, the drain of the transistor M2, and the second terminal of the resistor R1. The transistor M4 has a source and a backgate that are connected to the output terminal of the constant voltage VREF. Note that the transistor M4 functions as a source follower arranged to enhance current capacity of the constant voltage generation circuit 1.

In other words, in the first embodiment (FIG. 2) described above, the gate and backgate of the transistor M1, the drain of the transistor M2, and the second terminal of the resistor R1 are directly connected to the output terminal of the constant voltage VREF, while in the second embodiment (FIG. 4) they are connected to the output terminal of the constant voltage via the source follower.

With this structure, the current capacity of the constant voltage generation circuit 1 can be enhanced without affecting the temperature characteristic of the ED reference voltage source (the transistors M1 and M2). Note that as a matter of course, as the transistor M4 it is preferred to use an element having larger current capacity than the transistor M1 or M2.

### Third Embodiment

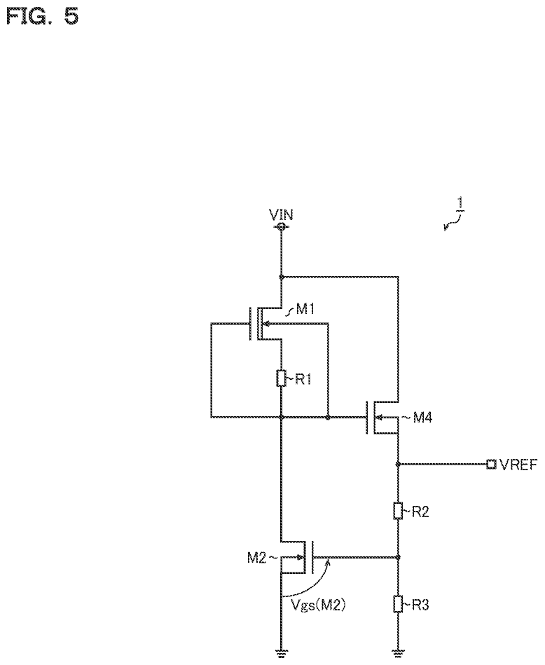

FIG. 5 is a diagram illustrating a third embodiment of the constant voltage generation circuit. The constant voltage generation circuit 1 of this embodiment is based on the second embodiment (FIG. 4) described above and is provided with additional resistors R2 and R3.

The resistor R2 has a first terminal connected to the output terminal of the constant voltage VREF. A second terminal of the resistor R2 and a first terminal of the resistor R3 are connected to the gate of the transistor M2. A second terminal of the resistor R3 is connected to the ground terminal. The resistors R2 and R3 connected in this way function as a resistor voltage divider that divides the constant voltage VREF and applies the divided voltage to the gate of the transistor M2.

In other words, in the first embodiment (FIG. 2) and the second embodiment (FIG. 4) described above, the gate of the transistor M2 is directly connected to the output terminal of the constant voltage VREF, while in the third embodiment (FIG. 5) it is connected to the output terminal of the constant voltage via the resistor voltage divider.

With this structure, it is possible to generate the constant voltage VREF (=Vgs(M2)×((R2+R3)/R3)) higher than that in the first embodiment (FIG. 2) or the second embodiment (FIG. 4).

Note that this embodiment is based on the second embodiment (FIG. 4), but it may be based on the first embodiment (FIG. 2) and add the resistors R2 and R3.

### Fourth Embodiment

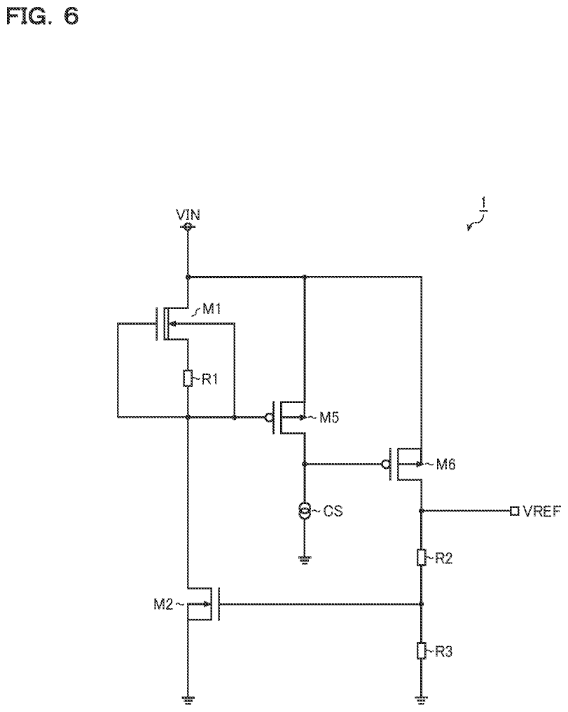

FIG. 6 is a diagram illustrating a fourth embodiment of the constant voltage generation circuit. The constant voltage generation circuit 1 of this embodiment is based on the third embodiment (FIG. 5) described above and includes P-channel MOS field effect transistors M5 and M6 and a current source CS instead of the transistor M4.

Sources and backgates of the transistors M5 and M6 are all connected to the application terminal of the input voltage VIN. The transistor M5 has a gate connected to the gate and backgate of the transistor M1, the drain of the transistor M2, and the second terminal of the resistor R1. The transistor M6 has a gate connected to a drain of the transistor M5 and a first terminal of the current source CS. A second terminal of the current source CS is connected to the ground terminal. The transistor M6 has a drain connected to the output terminal of the constant voltage VREF. The transistors M5 and M6 and the current source CS connected in this way function as a source follower arranged to enhance current capacity of the constant voltage generation circuit 1.

In this way, the structure in which a PMOSFET is used as the source follower can operate in a state where the input voltage VIN is lower (i.e. VIN-VREF is smaller) than that in the second embodiment (FIG. 4) or the third embodiment (FIG. 5) in which an NMOSFET is used as the source follower. In particular, it can be said that this structure is effective when an output target value of the constant voltage VREF is high.

### Fifth Embodiment

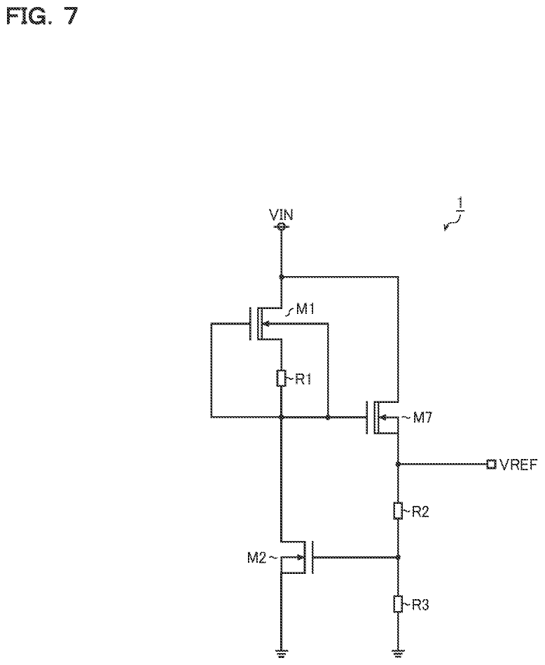

FIG. 7 is a diagram illustrating a fifth embodiment of the constant voltage generation circuit. The constant voltage generation circuit 1 of this embodiment is based on the third embodiment (FIG. 5) described above and includes a depression type N-channel MOS field effect transistor M7 instead of the enhancement type transistor M4.

The structure in which the depression type NMOSFET is used as the source follower in this way can output the constant voltage VREF following the input voltage VIN from just after the input voltage VIN is applied.

### Sixth Embodiment

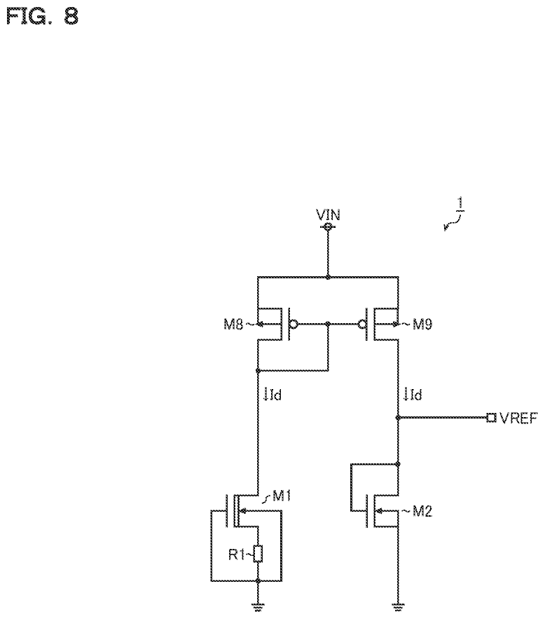

FIG. 8 is a diagram illustrating a sixth embodiment of the constant voltage generation circuit. The constant voltage generation circuit 1 of this embodiment has a structure similar to that of the first to fifth embodiments described above, in which the resistor R1 is inserted between the gate and source of the transistor M1 forming the ED reference voltage source, and is modified so that the drain current Id is supplied to the transistor M2 via the current mirror constituted of P-channel MOS field effect transistors M8 and M9.

The drain of the transistor M1 is connected to a drain of the transistor M8 (i.e. an input terminal of the current mirror). The source of the transistor M1 is connected to the first terminal of the resistor R1. The gate and backgate of the transistor M1 and the second terminal of the resistor R1 are all connected to the ground terminal.

Sources and backgates of the transistors M8 and M9 are connected to the application terminal of the input voltage VIN. Gates of the transistors M8 and M9 are connected to the drain of the transistor M8. The drain of the transistor M9 (i.e. the output terminal of the current mirror) and the drain and gate of the transistor M2 are connected to the output terminal of the constant voltage VREF. The source of the transistor M2 is connected to the ground terminal.

In this way, even the circuit form, in which the drain current Id of the transistor M1 is supplied to the transistor M2 via the current mirror, can obtain the effect of inserting the resistor R1 as described above.

<Consideration about Input Voltage Characteristic>

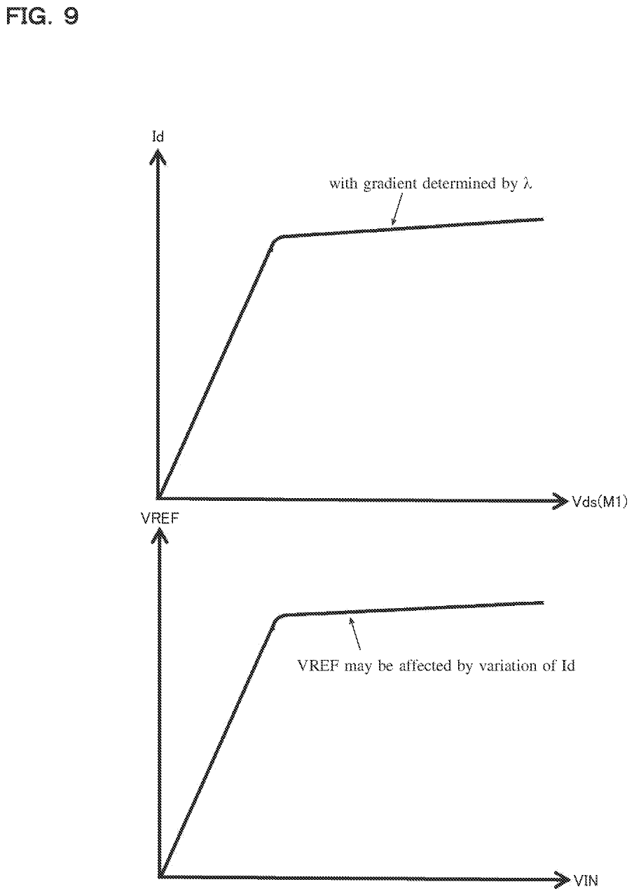

FIG. 9 is a diagram illustrating Vds(M1)-Id characteristic and VIN-VREF characteristic in the comparative example (FIG. 1) described above. As described above, in the ED type reference voltage source, the transistor M1 functions as the constant current source that determines the drain current Id, and the constant voltage VREF is determined in accordance with the gate-source voltage Vgs(M2) of the transistor M2 in which the drain current Id flows.

If the transistor M1 is operating in a saturated region, the drain current Id is substantially constant, and hence the constant voltage VREF should be ideally constant without depending on the input voltage VIN. However, the actual drain current Id is not completely constant and has a small gradient of dependence on Vds determined by channel length modulation parameter λ, as expressed by Id∝(1+λ×Vds).

Note that the above-mentioned channel length modulation parameter λ is a characteristic unique to a device and varies also depending on the element size. Therefore, if the input voltage VIN (therefore the drain-source voltage Vds(M1)) varies, the drain current Id flowing in the transistor M1 varies, and hence the constant voltage VREF may vary.

In the following description, in view of the above consideration, a novel embodiment is proposed in which variation of the drain current Id due to input voltage variation is suppressed so that output accuracy of the constant voltage VREF can be improved.

### Seventh Embodiment

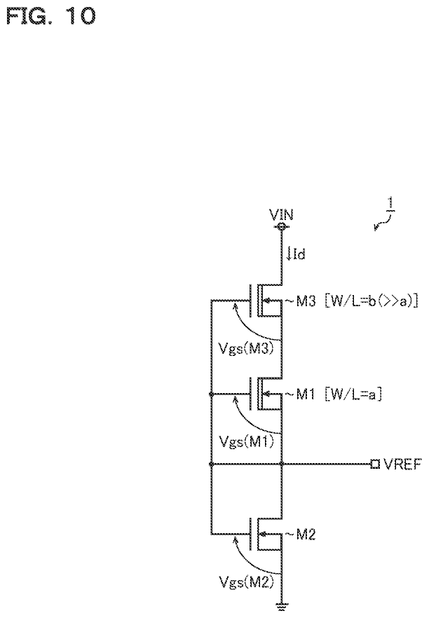

FIG. 10 is a diagram illustrating a seventh embodiment of the constant voltage generation circuit. The constant voltage generation circuit 1 of this embodiment is based on the comparative example (FIG. 1) described above and further includes a depression type N-channel MOS field effect transistor M3.

The transistor M3 has a drain connected to the application terminal of the input voltage VIN. The transistor M3 has a source and a backgate that are connected to the drain of the transistor M1. The transistor M3 has a gate connected to the gate of the transistor M1. In other words, the drain of the transistor M1 is connected to the application terminal of the input voltage VIN via the transistor M3.

Note that the drain-source voltage Vds(M1) of the transistor M1 should be set to 0.2 V or more when using the transistor M1 in the saturated region, and the size of the transistor M3 should be determined to satisfy the above condition. Therefore, the transistor M3 is designed to have a W/L value (i.e. a ratio of channel width W to channel length L) sufficiently larger than that of the transistor M1. For instance, when W/L of the transistor M1 is denoted by “a” while W/L of the transistor M2 is denoted by “b”, it is preferred to design so that b is approximately 20 to 100 times of a.

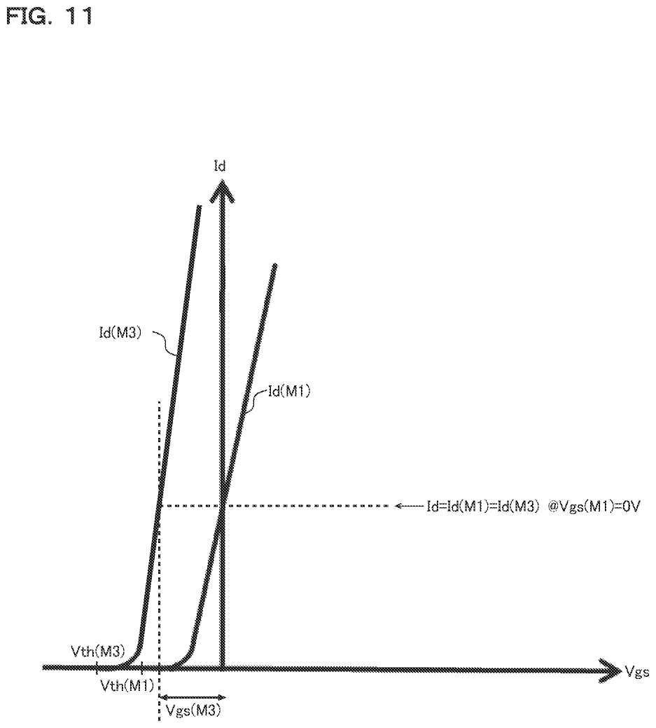

FIG. 11 is a diagram illustrating variation reduction effect of the drain current Id by adding the transistor M3. Note that the horizontal axis represents the gate-source voltage Vgs, and the vertical axis represents the drain current Id.

As described above, W/L of the transistor M3 is designed to be sufficiently larger than W/L of the transistor M1. Therefore, the ON threshold value voltage Vth(M3) of the transistor M3 is sufficiently smaller than the ON threshold value voltage Vth(M1) of the transistor M1. As a result, the transistor M1 is more dominant in determining the drain current Id than the transistor M3. In other words, when the drain current determined by the transistor M1 is denoted by Id(M1), Id=Id(M1) is satisfied.

In addition, the transistors M1 and M3 are connected in series, and hence the drain current Id determined as described above flows in the transistor M3, too. As a result, the transistor M3 is stabilized in a state where the drain current Id(M1) flows (in a state where Id=Id(M1)=id(M3) is satisfied). In other words, the transistor M3 is clamped in a state where a negative voltage is generated as the gate-source voltage Vgs(M3).

The clamp voltage in this case is approximately 0.2 V or more, as it should be a voltage in the range where the transistor M1 is in the saturated region, and it is necessary to consider an influence of characteristics and size of the element.

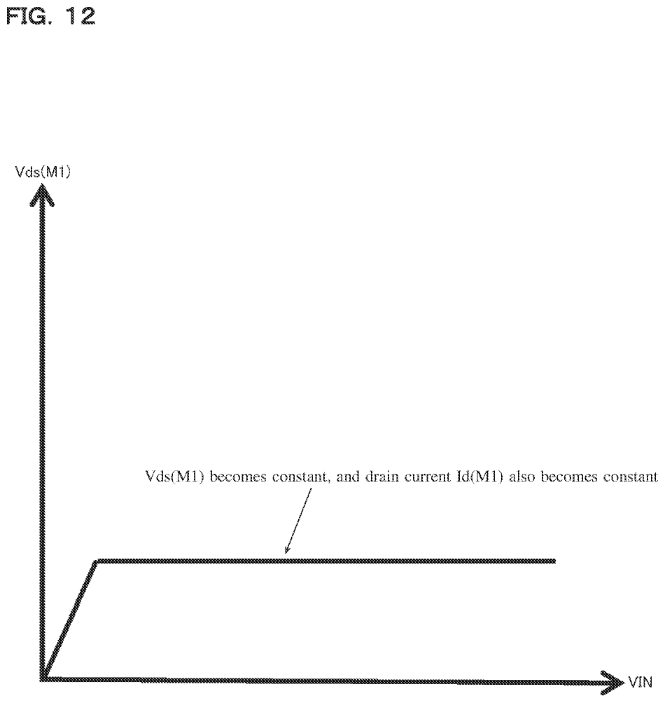

FIG. 12 is a diagram illustrating VIN-Vds(M1) characteristic in the seventh embodiment. The series of operation described above enables the drain-source voltage Vds(M1) of the transistor M1 to be substantially constant even if the input voltage VIN varies. Therefore, variation of the drain current Id due to input voltage variation can be suppressed, and output accuracy of the constant voltage VREF can be improved.

### Eighth Embodiment

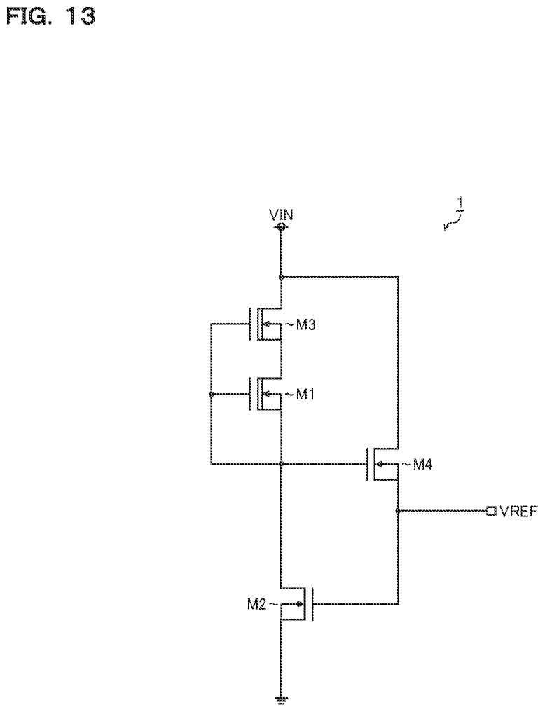

FIG. 13 is a diagram illustrating an eighth embodiment of the constant voltage generation circuit. The constant voltage generation circuit 1 of this embodiment is based on the seventh embodiment (FIG. 10) described above and further includes the enhancement type N-channel MOS field effect transistor M4.

The drain of the transistor M4 is connected to the application terminal of the input voltage VIN. The gate of the transistor M4 is connected to the gate and backgate of the transistor M1, the drain of the transistor M2, and the gate of the transistor M3. The source and backgate of the transistor M4 are connected to the output terminal of the constant voltage VREF. Note that the transistor M4 functions as a source follower arranged to enhance current capacity of the constant voltage generation circuit 1.

In other words, in the seventh embodiment (FIG. 10) described above, the gate and backgate of the transistor M1, the drain of the transistor M2, and the gate of the transistor M3 are directly connected to the output terminal of the constant voltage VREF, while in the eighth embodiment (FIG. 13) they are connected to the output terminal of the constant voltage via the source follower.

With this structure, current capacity of the constant voltage generation circuit 1 can be enhanced without affecting the temperature characteristic of the ED reference voltage source (the transistors M1 and M2). Note that as a matter of course, as the transistor M4 it is preferred to use an element having larger current capacity than the transistor M1 or M2.

### Ninth Embodiment

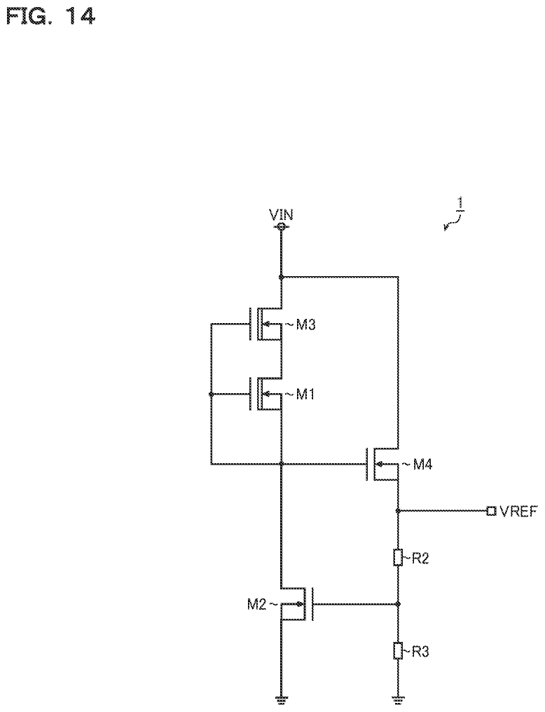

FIG. 14 is a diagram illustrating a ninth embodiment of the constant voltage generation circuit. The constant voltage generation circuit 1 of this embodiment is based on the eighth embodiment (FIG. 13) and is provided with the additional resistors R2 and R3.

The first terminal of the resistor R2 is connected to the output terminal of the constant voltage VREF. The second terminal of the resistor R2 and the first terminal of the resistor R3 are connected to the gate of the transistor M2. The second terminal of the resistor R3 is connected to the ground terminal. The resistors R2 and R3 connected in this way function as a resistor voltage divider that divides the constant voltage VREF and applies the divided voltage to the gate of the transistor M2.

In other words, in the seventh embodiment (FIG. 10) and the eighth embodiment (FIG. 13) described above, the gate of the transistor M2 is directly connected to the output terminal of the constant voltage VREF, while in the ninth embodiment (FIG. 14) it is connected to the output terminal of the constant voltage via the resistor voltage divider.

With this structure, it is possible to generate constant voltage VREF (=Vgs(M2)×((R2+R3)/R3)) higher than that in the seventh embodiment (FIG. 10) or the eighth embodiment (FIG. 13) described above.

Note that this embodiment is based on the eighth embodiment (FIG. 13), but it may be based on the seventh embodiment (FIG. 10) and add the resistors R2 and R3.

### Tenth Embodiment

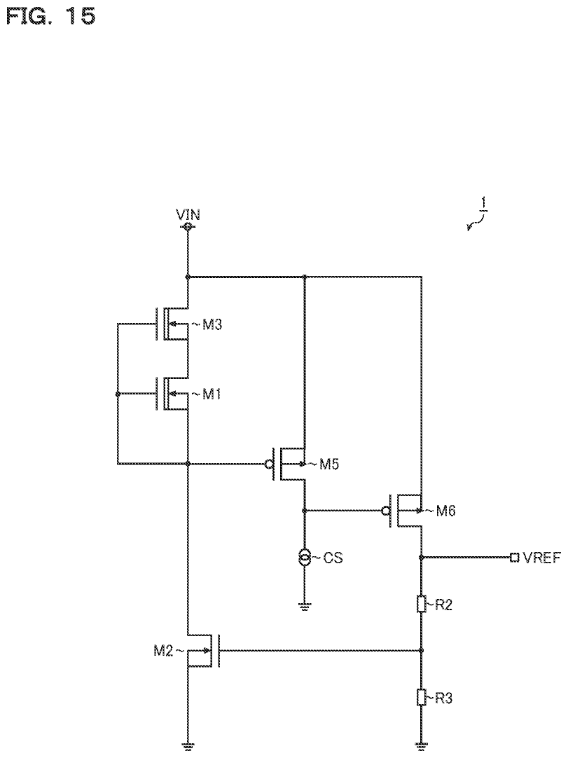

FIG. 15 is a diagram illustrating a tenth embodiment of the constant voltage generation circuit. The constant voltage generation circuit 1 of this embodiment is based on the ninth embodiment (FIG. 14) described above and includes the P-channel MOS field effect transistors M5 and M6 and the current source CS instead of the transistor M4.

The sources and backgates of the transistors M5 and M6 are all connected to the application terminal of the input voltage VIN. The gate of the transistor M5 is connected to the gate and backgate of the transistor M1, the drain of the transistor M2, and the gate of the transistor M3. The gate of the transistor M6 is connected to the drain of the transistor M5 and the first terminal of the current source CS. The second terminal of the current source CS is connected to the ground terminal. The drain of the transistor M6 is connected to the output terminal of the constant voltage VREF. The transistors M5 and M6 and the current source CS connected in this way function as the source follower arranged to enhance current capacity of the constant voltage generation circuit 1.

In this way, the structure in which the PMOSFETs are used as the source follower can operate in a state where the input voltage VIN is lower (i.e. VIN-VREF is smaller) than that in the eighth embodiment (FIG. 13) or the ninth embodiment (FIG. 14) in which the NMOSFET is used as the source follower. In particular, it can be said that this structure is effective when the output target value of the constant voltage VREF is high.

### Eleventh Embodiment

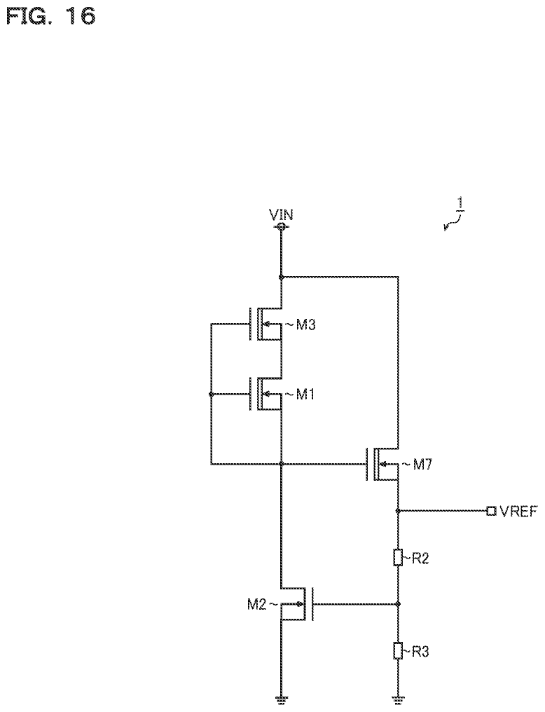

FIG. 16 is a diagram illustrating an eleventh embodiment of the constant voltage generation circuit. The constant voltage generation circuit 1 of this embodiment is based on the ninth embodiment (FIG. 14) and includes the depression type N-channel MOS field effect transistor M7 instead of the enhancement type transistor M4.

In this way, the structure in which the depression type NMOSFET is used as the source follower can output the constant voltage VREF following the input voltage VIN from just after the input voltage VIN is applied.

### Twelfth Embodiment

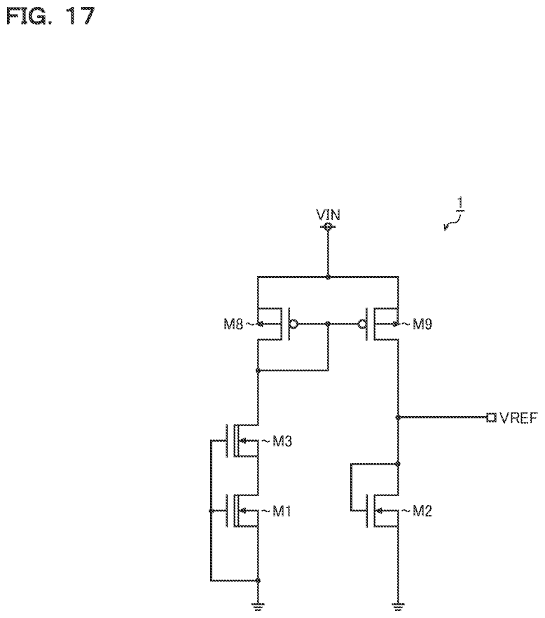

FIG. 17 is a diagram illustrating a twelfth embodiment of the constant voltage generation circuit. Similarly to the seventh to eleventh embodiments described above, the constant voltage generation circuit 1 of this embodiment has the structure in which the transistor M3 is connected to the drain of the transistor M1 constituting the ED reference voltage source, and is modified so that the drain current Id is supplied to the transistor M2 via the current mirror constituted of the P-channel MOS field effect transistors M8 and M9.

The drain of the transistor M3 is connected to the drain of the transistor M8 (i.e. the input terminal of the current mirror). The source and backgate of the transistor M3 are connected to the drain of the transistor M1. In other words, the drain of the transistor M1 is connected to the input terminal of the current mirror via the transistor M3. The gate and backgate of the transistor M1 and the gate of the transistor M3 are connected to the ground terminal.

The sources and backgates of the transistors M8 and M9 are connected to the application terminal of the input voltage VIN. The gates of the transistors M8 and M9 are connected to the drain of the transistor M8. The drain of the transistor M9 (i.e. the output terminal of the current mirror) and the drain and gate of the transistor M2 are connected to the output terminal of the constant voltage VREF. The source of the transistor M2 is connected to the ground terminal.

In this way, even the circuit form, in which the drain current Id of the transistor M1 is supplied to the transistor M2 via the current mirror, can obtain the effect of inserting the transistor M3 as described above.

### Thirteenth Embodiment

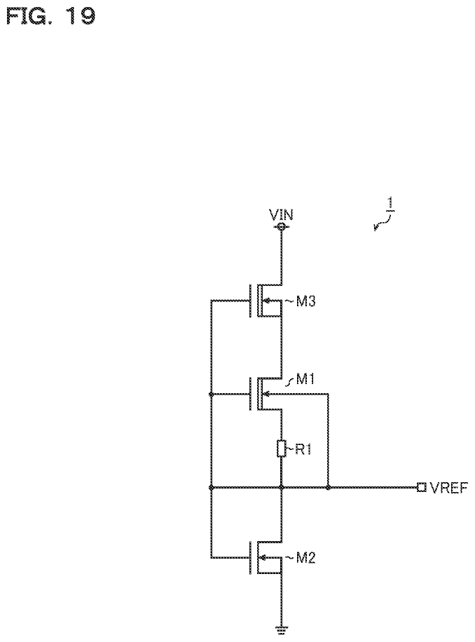

FIG. 18 is a diagram illustrating a thirteenth embodiment of the constant voltage generation circuit. The constant voltage generation circuit 1 of this embodiment is based on the seventh embodiment (FIG. 10) described above and further includes the resistor R1.

The first terminal of the resistor R1 is connected to the source of the transistor M1. The second terminal of the resistor R1 is connected to the gate and backgate of the transistor M1 and the output terminal of the constant voltage VREF. In this way, the resistor R1 is connected between the gate of the transistor M1 and source, and between the backgate and source of the transistor M1.

This embodiment can obtain the variation suppression effect of the drain current Id by inserting the resistor R1. Therefore, not only the variation of the drain current Id due to the input voltage variation but also the variation of the drain current Id due to the process variation can be suppressed, and hence output accuracy of the constant voltage VREF can be further improved.

Note that this embodiment is based on the seventh embodiment (FIG. 10), but it may be based on the eighth to twelfth embodiment, so that the resistor R1 is inserted between the gate and source of the transistor M1.

<Summary>

In the following description, the various embodiments disclosed in this specification are summarized and described.

For instance, the constant voltage generation circuit disclosed in this specification includes a depression type first transistor and an enhancement type second transistor that constitute an ED type reference voltage source, and a resistor connected between gate and source of the first transistor (first structure).

Note that the constant voltage generation circuit having the first structure described above may have a structure in which the first transistor and the second transistor are NMOSFETs (second structure).

In addition, the constant voltage generation circuit having the second structure described above may have a structure in which the first transistor has a drain connected to an application terminal of an input voltage, the second transistor has a source connected to a reference potential terminal, a gate of the first transistor and a drain of the second transistor are connected to an output terminal of the constant voltage directly or via a source follower, and a gate of the second transistor is connected to the output terminal of the constant voltage directly or via a resistor voltage divider (third structure).

In addition, the constant voltage generation circuit having the third structure described above may have a structure in which the source follower includes an NMOSFET having a drain connected to an application terminal of the input voltage, a gate connected to the gate of the first transistor and the drain of the second transistor, and a source connected to the output terminal of the constant voltage (fourth structure).

In addition, in the constant voltage generation circuit having the fourth structure described above may have a structure in which the NMOSFET is a depression type (fifth structure).

In addition, the constant voltage generation circuit having the third structure described above may have a structure in which the source follower includes a first PMOSFET having a source connected to the application terminal of the input voltage, and a gate connected to the gate of the first transistor and the drain of the second transistor; a second PMOSFET having a source connected to the application terminal of the input voltage, a gate connected to a drain of the first PMOSFET, and a drain connected to the output terminal of the constant voltage; and a current source connected between the reference potential terminal and the drain of the first PMOSFET as well as the gate of the second PMOSFET (sixth structure).

In addition, the constant voltage generation circuit having the second structure described above may have a structure in which the drain of the first transistor is connected to the input terminal of the current mirror, the output terminal of the current mirror and the drain and gate of the second transistor are connected to the output terminal of the constant voltage, and the gate of the first transistor and the source of the second transistor are connected to the reference potential terminal (seventh structure).

In addition, the constant voltage generation circuit having any one of the first to seventh structures described above may have a structure in which the resistor is a base resistor having a positive temperature characteristic (eighth structure).

In addition, the constant voltage generation circuit having any one of the first to seventh structures described above may have a structure in which the resistor is a poly resistor having a negative temperature characteristic (ninth structure).

In addition, the constant voltage generation circuit having any one of the first to ninth structures described above may have a structure in which drain current flowing in the first transistor is 100 nA or more and less than 1 μA, and the resistor has a resistance of 100 kΩ or more and less than 1 MΩ (tenth structure).

Further for example, another constant voltage generation circuit disclosed in this specification includes a depression type first transistor and an enhancement type second transistor that constitute an ED type reference voltage source, and a depression type third transistor that is connected to a drain of the first transistor and has larger W/L than the first transistor (eleventh structure).

Note that the constant voltage generation circuit having the eleventh structure described above may have a structure in which the first transistor, the second transistor, and the third transistor are NMOSFETs (twelfth structure).

In addition, the constant voltage generation circuit having the twelfth structure described above may have a structure in which the drain of the first transistor is connected to an application terminal of an input voltage via the third transistor, a source of the second transistor is connected to the reference potential terminal, gates of the first transistor and the third transistor and a drain of the second transistor are connected to the output terminal of the constant voltage directly or via a source follower, and the gate of the second transistor is connected to the output terminal of the constant voltage directly or via a resistor voltage divider (thirteenth structure).

The constant voltage generation circuit having the thirteenth structure described above may have a structure in which the source follower includes an NMOSFET having a drain connected to an application terminal of the input voltage, a gate connected to the gates of the first transistor and the third transistor and the drain of the second transistor, and a source connected to the output terminal of the constant voltage (fourteenth structure).

In addition, the constant voltage generation circuit having the fourteenth structure described above may have a structure in which the NMOSFET is a depression type (fifteenth structure).

In addition, the constant voltage generation circuit having the thirteenth structure described above may have a structure in which the source follower includes a first PMOSFET having a source connected to the application terminal of the input voltage, a gate connected to the gates of the first transistor and the third transistor and the drain of the second transistor; a second PMOSFET having a source connected to the application terminal of the input voltage, a gate connected to the drain of the first PMOSFET, and a drain connected to the output terminal of the constant voltage; and a current source connected between the reference potential terminal and the drain of the first PMOSFET as well as the gate of the second PMOSFET (sixteenth structure).

In addition, the constant voltage generation circuit having the twelfth structure described above may have a structure in which the drain of the first transistor is connected to the input terminal of the current mirror via the third transistor, the output terminal of the current mirror and the drain and gate of the second transistor are connected to the output terminal of the constant voltage, and the gates of the first transistor and the third transistor and the source of the second transistor are connected to the reference potential terminal (seventeenth structure).

The constant voltage generation circuit having any one of the eleventh to seventeenth structures described above may have a structure further including a resistor connected between gate and source of the first transistor (eighteenth structure).

In addition, the constant voltage generation circuit having the eighteenth structure described above may have a structure in which the resistor is a base resistor having a positive temperature characteristic (nineteenth structure).

In addition, the constant voltage generation circuit having the eighteenth structure described above may have a structure in which the resistor is a poly resistor having a negative temperature characteristic (twelfth structure).

<Other Variations>

Note that other than the embodiments described above, the various technical features disclosed in this specification can be variously modified without deviating from the spirit of the technical creation. In other words, the embodiments described above are merely examples in every aspect and should not be interpreted as limitations. The technical scope of the present invention is not limited to the embodiments described above but should be interpreted to include all modifications within meanings and ranges equivalent to the claims.

### INDUSTRIAL APPLICABILITY

The constant voltage generation circuit disclosed in this specification can be appropriately used as means arranged to generate a reference voltage or a threshold value voltage in a semiconductor device, for example.

### LIST OF REFERENCE SIGNS

1 constant voltage generation circuit
CS current source
M1 NMOSFET (corresponding to depression type first transistor)
M2 NMOSFET (corresponding to enhancement type second transistor)
M3 NMOSFET (corresponding to depression type third transistor)
M4 NMOSFET (enhancement type)
M5, M6 PMOSFET
M7 NMOSFET (depression type)
M8, M9 PMOSFET
R1, R2, R3 resistor

1. A constant voltage generation circuit comprising:
a depression type first transistor and an enhancement type second transistor that constitute an ED type reference voltage source; and
a resistor connected between gate and source of the first transistor.

2. The constant voltage generation circuit according to claim 1, wherein the first transistor and the second transistor are NMOSFETs.

3. The constant voltage generation circuit according to claim 2, wherein
a drain of the first transistor is connected to an application terminal of an input voltage,
a source of the second transistor is connected to a reference potential terminal,
a gate of the first transistor and a drain of the second transistor are connected to an output terminal of a constant voltage directly or via a source follower, and
a gate of the second transistor is connected to the output terminal of the constant voltage directly or via a resistor voltage divider.

4. The constant voltage generation circuit according to claim 3, wherein the source follower includes an NMOSFET having a drain connected to the application terminal of the input voltage, a gate connected to the gate of the first transistor and the drain of the second transistor, and a source connected to the output terminal of the constant voltage.

5. The constant voltage generation circuit according to claim 4, wherein the NMOSFET is a depression type.

6. The constant voltage generation circuit according to claim 3, wherein the source follower includes:
a first PMOSFET having a source connected to the application terminal of the input voltage, and a gate connected to the gate of the first transistor and the drain of the second transistor;
a second PMOSFET having a source connected to the application terminal of the input voltage, a gate connected to a drain of the first PMOSFET, and a drain connected to the output terminal of the constant voltage; and
a current source connected between the reference potential terminal and the drain of the first PMOSFET as well as the gate of the second PMOSFET.

7. The constant voltage generation circuit according to claim 2, wherein
the drain of the first transistor is connected to the input terminal of the current mirror,
the output terminal of the current mirror and the drain and gate of the second transistor are connected to the output terminal of the constant voltage, and
the gate of the first transistor and the source of the second transistor are connected to the reference potential terminal.

8. The constant voltage generation circuit according to claim 1, wherein the resistor is a base resistor having a positive temperature characteristic.

9. The constant voltage generation circuit according to claim 1, wherein the resistor is a poly resistor having a negative temperature characteristic.

10. The constant voltage generation circuit according to claim 1, wherein
drain current flowing in the first transistor is 100 nA or more and less than 1 μA, and the resistor has a resistance of 100 kW or more and less than 1 MΩ.

11. A constant voltage generation circuit comprising:
a depression type first transistor and an enhancement type second transistor that constitute an ED type reference voltage source; and
a depression type third transistor that is connected to a drain of the first transistor and has larger W/L than the first transistor.

12. The constant voltage generation circuit according to claim 11, wherein the first transistor, the second transistor, and the third transistor are NMOSFETs.

13. The constant voltage generation circuit according to claim 12, wherein
the drain of the first transistor is connected to an application terminal of an input voltage via the third transistor,
a source of the second transistor is connected to the reference potential terminal,
gates of the first transistor and the third transistor and a drain of the second transistor are connected to the output terminal of the constant voltage directly or via a source follower, and
the gate of the second transistor is connected to the output terminal of the constant voltage directly or via a resistor voltage divider.

14. The constant voltage generation circuit according to claim 13, wherein the source follower includes an NMOSFET having a drain connected to an application terminal of the input voltage, a gate connected to the gates of the first transistor and the third transistor and the drain of the second transistor, and a source connected to the output terminal of the constant voltage.

15. The constant voltage generation circuit according to claim 14, wherein the NMOSFET is a depression type.

16. The constant voltage generation circuit according to claim 13, wherein the source follower includes:
a first PMOSFET having a source connected to the application terminal of the input voltage, a gate connected to the gates of the first transistor and the third transistor and the drain of the second transistor;
a second PMOSFET having a source connected to the application terminal of the input voltage, a gate connected to the drain of the first PMOSFET, and a drain connected to the output terminal of the constant voltage; and
a current source connected between the reference potential terminal and the drain of the first PMOSFET as well as the gate of the second PMOSFET.

17. The constant voltage generation circuit according to claim 12, wherein
the drain of the first transistor is connected to the input terminal of the current mirror via the third transistor,
the output terminal of the current mirror and the drain and gate of the second transistor are connected to the output terminal of the constant voltage, and
the gates of the first transistor and the third transistor and the source of the second transistor are connected to the reference potential terminal.

18. The constant voltage generation circuit according to claim 11, further comprising a resistor connected between gate and source of the first transistor.

19. The constant voltage generation circuit according to claim 18, wherein the resistor is a base resistor having a positive temperature characteristic.

20. The constant voltage generation circuit according to claim 18, wherein the resistor is a poly resistor having a negative temperature characteristic.
